(19) United States
(12) Patent Application Publication
(10) Pub. No.: US 2026/0053065 A1
(43) Pub. Date: Feb. 19, 2026

(54) SEMICONDUCTOR PACKAGE

(71) Applicant: SAMSUNG ELECTRONICS CO., LTD., SUWON-SI (KR)

(72) Inventor: Kiwon BAEK, Suwon-si (KR)

(21) Appl. No.: 19/056,896

(22) Filed: Feb. 19, 2025

(30) Foreign Application Priority Data
Aug. 14, 2024 (KR) 10-2024-0109353

(51) Int. Cl. H01L 25/18; H01L 23/00; H01L 23/498; H10B 80/00; H10D 80/30

(52) U.S. Cl. CPC H01L 25/18; H01L 24/48; H10B 80/00; H10D 80/30; H01L 23/49816; H01L 2224/48137; H01L 2224/48145; H01L 2224/48227; H01L 2225/06506; H01L 2225/0651; H01L 2225/06562; H01L 2924/1431

(57) ABSTRACT

A semiconductor package includes a substrate including first bonding pads. At least one chip stack is on the substrate and includes a plurality of semiconductor chips stacked thereon. The semiconductor chips include first connection pads electrically connected to the first bonding pads, bonding wires electrically connecting the substrate to the chip stack, and connection bumps below the substrate. The semiconductor chips include a second group of semiconductor chips stacked on a first group of semiconductor chips. An uppermost semiconductor chip in the first group of semiconductor chips or a lowermost semiconductor chip in the second group of semiconductor chips further includes second connection pads electrically connected to the first connection pads, respectively. The bonding wires include first bonding wires electrically connecting the first connection pads of the semiconductor chips to each other, and second bonding wires electrically connecting the second connection pads and the first bonding pads to each other.

### CROSS-REFERENCE TO RELATED APPLICATION(S)

This application claims priority under 35 U.S.C. § 119 to Korean Patent Application No. 10-2024-0109353, filed on Aug. 14, 2024 in the Korean Intellectual Property Office, the disclosure of which is incorporated by reference in its entirety herein.

### 1. TECHNICAL FIELD

The present inventive concept relates to a semiconductor package.

### 2. DISCUSSION OF RELATED ART

Consumer demand for high performance and high capacity semiconductor packages mounted on electronic devices has increased along with the advancement of the information society. Accordingly, research is being conducted concerning semiconductor packages having increased signal characteristics of a plurality of vertically stacked semiconductor chips.

### SUMMARY

An aspect of embodiment of the present inventive concept is to provide a semiconductor package having increased signal characteristics.

According to an embodiment of the present inventive concept, a semiconductor package includes a substrate including first bonding pads. At least one chip stack is disposed on the substrate. The at least one chip stack includes a plurality of semiconductor chips stacked on the substrate. The plurality of semiconductor chips includes first connection pads electrically connected to the first bonding pads. Bonding wires electrically connect the substrate to the at least one chip stack. Connection bumps are arranged below the substrate. The plurality of semiconductor chips includes a first group of semiconductor chips and a second group of semiconductor chips stacked on the first group of semiconductor chips. Any one of an uppermost semiconductor chip in the first group of semiconductor chips and a lowermost semiconductor chip in the second group of semiconductor chips further includes second connection pads electrically connected to the first connection pads, respectively. The bonding wires include first bonding wires electrically connecting the first connection pads of each of the plurality of semiconductor chips to each other, and second bonding wires electrically connecting the second connection pads and the first bonding pads to each other.

According to an embodiment of the present inventive concept, a semiconductor package includes a substrate including first bonding pads. A plurality of semiconductor chips is stacked on the substrate. Each of the plurality of semiconductor chips includes at least one of a first connection pad or a second connection pad. Bonding wires electrically connect the substrate to the plurality of semiconductor chips. The plurality of semiconductor chips include an intermediate semiconductor chip including the first connection pad and the second connection pad electrically connected to the first connection pad. Lower semiconductor chips are stacked below the intermediate semiconductor chip. The lower semiconductor chips including the first connection pad. Upper semiconductor chips are stacked on the intermediate semiconductor chip. The upper semiconductor chips including the first connection pad. The bonding wires include a first bonding wire electrically connecting the first connection pads of each of the intermediate semiconductor chip, the lower semiconductor chips, and the upper semiconductor chips to each other. A second bonding wire electrically connecting the second connection pad of the intermediate semiconductor chip to the first bonding pads of the substrate.

According to an embodiment of the present inventive concept, a semiconductor package includes a substrate including first and second bonding pads. A plurality of semiconductor chips is stacked on the substrate. Each of the plurality of semiconductor chips includes a signal pad and a power pad. Bonding wires electrically connect the substrate to the plurality of semiconductor chips. Any one semiconductor chip, among the plurality of semiconductor chips, further includes a branch pad electrically connected to the signal pad. The bonding wires include a first bonding wire electrically connecting the signal pad of each of the plurality of semiconductor chips to each other. A second bonding wire electrically connecting the branch pad of any one semiconductor chip to the first bonding pad. A third bonding wire electrically connecting the power pad of each of the plurality of semiconductor chips to the second bonding pad.

### BRIEF DESCRIPTION OF DRAWINGS

The and other aspects, features, and advantages of embodiments of the present inventive concept will be more clearly understood from the following detailed description, taken in conjunction with the accompanying drawings, in which:

FIG. 1A is a perspective view of a semiconductor package according to an embodiment of the present inventive concept, and FIG. 1B is a cross-sectional view taken along line I-I′ of FIG. 1A according to an embodiment of the present inventive concept;

FIG. 2A is a perspective view of a semiconductor package according to an embodiment of the present inventive concept, and FIG. 2B is a cross-sectional view taken along line II-II′ of FIG. 2A according to an embodiment of the present inventive concept;

FIG. 3 is a perspective view of a semiconductor package according to an embodiment of the present inventive concept;

FIG. 4 is a perspective view of a semiconductor package according to an embodiment of the present inventive concept;

FIG. 5 is a view illustrating a storage system according to an embodiment of the present inventive concept;

FIG. 6 is a view illustrating a storage system according to a comparative example;

FIG. 7 is an eye diagram of a storage device according to an embodiment; and

FIG. 8 is an eye diagram of a storage device according to a comparative example.

### DETAILED DESCRIPTION OF EMBODIMENTS

Hereinafter, embodiments of the present inventive concept will be described with reference to the attached drawings. Unless otherwise specified, in this specification, terms, such as ‘upper portion’, ‘upper surface’, ‘lower portion’, ‘lower surface’, ‘side surface’, etc. are based on the drawings, and may vary in the directions in which components are actually arranged.

In addition, ordinal numbers, such as “first,” “second,” “third,” etc. may be used as labels for specific elements, steps, directions, etc. to distinguish various elements, steps, directions, etc. from each other. Terms that are not described using “first,” “second,” etc. in the specification may still be referred to as “first” or “second” in the claims. In addition, terms referenced by a particular ordinal number (e.g., “first” in a particular claim) may be described elsewhere with a different ordinal number (e.g., “second” in the specification or other claims).

The present inventive concept concerns a semiconductor package having a semiconductor chip of a chip stack, such as an intermediate semiconductor chip, that includes a second connection pad. The second connection pad forms a branch point of a signal path of the signal transmission line between a first group of semiconductor chips and a second group of semiconductor chips of the chip stack. The branch point formed by the second connection pad minimizes signal reflection and increases signal characteristics.

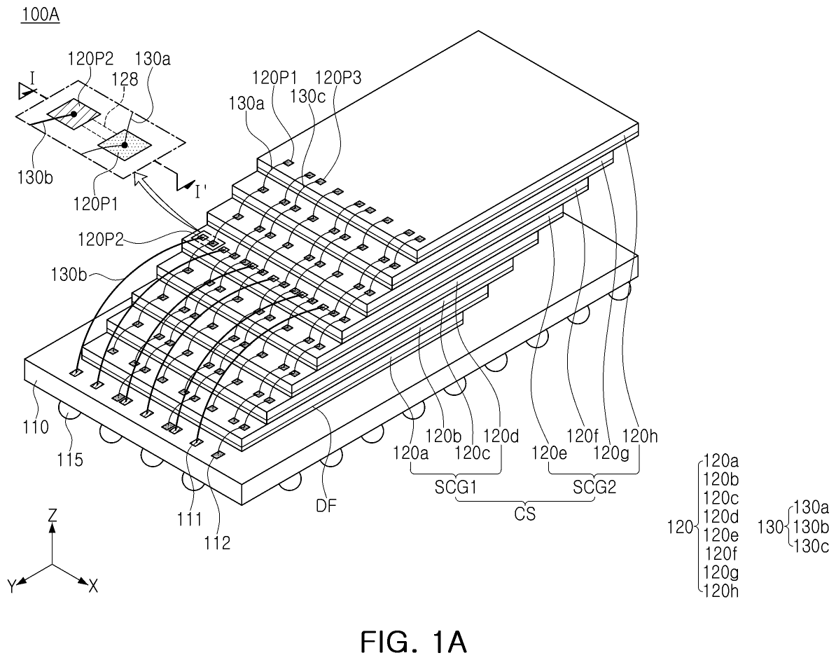

FIG. 1A is a perspective view of a semiconductor package 100A according to an embodiment, and FIG. 1B is a cross-sectional view taken along line I-I′ of FIG. 1A.

Referring to FIGS. 1A and 1B, the semiconductor package 100A according to an embodiment may include a substrate 110, a plurality of semiconductor chips 120, and bonding wires 130.

In an embodiment, the substrate 110 may be a semiconductor package substrate including a printed circuit board (PCB), a ceramic substrate, a glass substrate, a tape wiring board, or the like. For example, the substrate 110 may be a double-sided PCB or a multilayer PCB. According to an embodiment, a mold may be formed on (e.g., formed directly thereon) the substrate 110 to encapsulate the plurality of semiconductor chips 120. In an embodiment, the mold may include a thermosetting resin, such as an epoxy resin, a thermoplastic resin, such as a polyimide, or a resin obtained by impregnated these resins with an inorganic filler, for example, prepreg, Ajinomoto build-up film (ABF), FR-4, bismaleimide triazine (BT), or epoxy molding compound (EMC).

The substrate 110 may include bonding pads 111 and 112. In an embodiment, the bonding pads 111 and 112 may be arranged on an upper surface of the substrate 110 and may include at least one metal among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy including two or more metals thereof. The bonding pads 111 and 112 may be electrically connected to connection bumps 115 arranged below the substrate 110. In an embodiment, the connection bumps 115 may include, for example, tin (Sn) or an alloy (e.g., Sn—Ag—Cu) including tin (Sn). The substrate 110 may include a lower pad on which the connection bumps 115 are arranged and an internal circuit connecting the lower pad and the bonding pads 111 and 112 to each other. The connection bumps 115 may be electrically connected to an external device, such as a module substrate, a system board, etc.

In an embodiment, the bonding pads 111 and 112 may include first bonding pads 111 and second bonding pads 112 that are spaced apart from each other. For example, the first bonding pads 111 may be signal pads connected to input and output terminals of data signals, and the second bonding pads 112 may be power and ground pads connected to power terminals and ground terminals. The first bonding pads 111 and the second bonding pads 112 may be electrically insulated from each other.

In an embodiment, the plurality of semiconductor chips 120 may include, for example, non-volatile memory semiconductor chips, such as flash memory, phase-change random access memory (PRAM), magnetoresistive random access memory (MRAM), ferroelectric random access memory (FeRAM), or resistive random access memory (RRAM), and/or volatile memory semiconductor chips, such as dynamic random access memory (DRAM) or static random access memory (SRAM). The plurality of semiconductor chips 120 may include the same type of semiconductor chips. However, embodiments of the present inventive concept are not necessarily limited thereto. According to an embodiment, the plurality of semiconductor chips 120 may include different types of semiconductor chips.

The plurality of semiconductor chips 120 may be stacked in a vertical direction (e.g., a Z-direction) on the substrate 110. The plurality of semiconductor chips 120 may be attached to the substrate 110 or may be attached to each other by a bonding film DF. In an embodiment, the bonding film DF may be formed using an adhesive film, an adhesive paste, or the like. For example, the bonding film 125 may be a die attach film (DAF). However, embodiments of the present disclosure are not necessarily limited thereto. The plurality of semiconductor chips 120 may form at least one chip stack CS. In this specification, the term ‘chip stack CS’ may be understood to refer to a plurality of semiconductor chips 120 transmitting and receiving data through a single channel. In an embodiment shown in FIG. 1A, the plurality of semiconductor chips 120 includes eight semiconductor chips. However, embodiments of the present inventive concept are not necessarily limited thereto and the plurality of semiconductor chips 120 may be provided in a number greater or less than eight. In addition, the number of semiconductor chips 120 constituting one chip stack CS may be less than or greater than eight. In an embodiment, the plurality of semiconductor chips 120 may be stacked offset in one direction (e.g., a horizontal direction, such as a Y-direction) so that each of connection pads 120P1, 120P2, and 120P3 is exposed in the vertical direction (e.g., a Z-direction). In some embodiments, the plurality of semiconductor chips 120 may be aligned in the vertical direction (e.g., the Z-direction) so that the respective connection pads 120P1, 120P2, and 120P3 of the plurality of semiconductor chips 120 overlap each other (e.g., in the Z-direction).

The plurality of semiconductor chips 120 may include the connection pads 120P1, 120P2, and 120P3. In an embodiment, the connection pads 120P1, 120P2, and 120P3 may include one of copper (Cu), nickel (Ni), titanium (Ti), or aluminum (Al), or alloys thereof. In an embodiment, the connection pads 120P1, 120P2, and 120P3 may include first connection pads 120P1, second connection pads 120P2, and third connection pads 120P3. However, embodiments of the present inventive concept are not necessarily limited thereto and the number of the connection pads may vary. The first connection pads 120P1 may be signal pads for inputting and outputting a data signal, and the third connection pads 120P3 may be power pads for supplying power and ground voltages. The plurality of semiconductor chips 120 may each include the first connection pads 120P1 and the third connection pads 120P3.

In an embodiment, the second connection pads 120P2 (which may be referred to as ‘branch pads’ in this specification) may be formed on one semiconductor chip (e.g., ‘120e’ in FIG. 1A) located in the middle of the plurality of semiconductor chips 120 stacked in the vertical direction (e.g., the Z-direction). The second connection pads 120P2 may be electrically connected to the first connection pads 120P1 through a redistribution layer 128 and may be electrically connected to a first bonding pad 111 of the substrate 110 through a second bonding wire 130B. The second connection pads 120P2 may provide a branch point of a signal path connecting the plurality of semiconductor chips 120 to each other in the middle of the chip stack CS. Therefore, signal reflection may be minimized and signal integrity (SI) characteristics may be increased.

In an embodiment, the plurality of semiconductor chips 120 may include one semiconductor chip (e.g., 120e) including the second connection pad 120P2, one or more lower semiconductor chips (e.g., 120a, 120b, 120c, 120d) stacked below the one semiconductor chip (e.g., 120e), and one or more upper semiconductor chips (e.g., 120f, 120g, 120h) stacked above the one semiconductor chip (e.g., 120e). For example, in an embodiment the plurality of semiconductor chips 120 may include an intermediate semiconductor chip (e.g., 120e) including the first connection pad 120P1 and the second connection pad 120P2, lower semiconductor chips (e.g., 120a, 120b, 120c, and 120d) stacked below the intermediate semiconductor chip (e.g., 120e) and including the first connection pad 120P1, and upper semiconductor chips (e.g., 120f, 120g, and 120h) stacked on the intermediate semiconductor chip (e.g., 120e) and including the first connection pad 120P1. In an embodiment, the number of lower semiconductor chips (e.g., 120a, 120b, 120c, and 120d) and the number of upper semiconductor chips (e.g., 120f, 120g, and 120h) may be different from each other.

As illustrated in FIG. 1B, one semiconductor chip (e.g., the ‘intermediate semiconductor chip’) 120e may include a semiconductor layer 120B, a circuit layer 120C, and a redistribution layer 128 connecting (e.g., electrically connecting) the first connection pads 120P1 and the second connection pads 120P2 to each other.

In an embodiment, the semiconductor layer 120B may be a semiconductor wafer. For example, in an embodiment the semiconductor layer 120B may include a semiconductor element, such as silicon or germanium or a compound semiconductor, such as silicon carbide (SiC), gallium arsenide (GaAs), indium arsenide (InAs), and indium phosphide (InP). The semiconductor layer 120B may include a conductive region 122 and an isolation region 121. In an embodiment, the conductive region 122 may be, for example, a well doped with impurities or a structure doped with impurities. In an embodiment, the isolation region 121 is an element isolation structure having a shallow trench isolation (STI) structure and may include silicon oxide.

The circuit layer 120C may be disposed on (e.g., disposed directly thereon) the semiconductor layer 120B on which the conductive region 122 is formed. The circuit layer 120C may include individual devices ID, an interlayer insulating layer 123, and an interconnection structure 126.

In an embodiment, the individual devices ID may include, for example, FETs, such as planar FETs or FinFETs, memory devices, such as flash memory, DRAM, SRAM, EEPROM, PRAM, MRAM, FeRAM, or RRAM, logic devices, such as AND, OR, NOT, and various active devices and/or passive devices, such as system LSI, CIS, and MEMS.

The interlayer insulating layer 123 may be formed to cover the individual devices ID and the interconnection structure 126, thereby electrically separating the individual devices ID from each other. In an embodiment, the interlayer insulating layer 123 may include a non-metallic inorganic material, for example, at least one of silicon oxide (SiO) or silicon nitride (SiN). In an embodiment, the interlayer insulating layer 123 may include flowable oxide (FOX), tonen silazen (TOSZ), undoped silica glass (USG), borosilica glass (BSG), phosphosilaca glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX), flowable CVD (FCVD) oxide, or combinations thereof. At least a portion of the interlayer insulating layer 123 surrounding the interconnection structure 126 may be formed of a low-k layer. In an embodiment, the interlayer insulating layer 123 may be formed using a chemical vapor deposition (CVD), a flowable-CVD process, or a spin coating process.

The interconnection structure 126 may be disposed within the interlayer insulating layer 123. In an embodiment, the interconnection structure 126 may be formed as a multilayer structure including a plurality of vias and a plurality of wiring patterns formed of, for example, aluminum (Al), gold (Au), cobalt (Co), copper (Cu), nickel (Ni), lead (Pb), tantalum (Ta), tellurium (Te), titanium (Ti), or tungsten (W) or combinations thereof. In an embodiment, a barrier film including titanium (Ti), titanium nitride (TiN), tantalum (Ta), or tantalum nitride (TaN) may be disposed between the wiring pattern or/and the via and the interlayer insulating layer 123. The interconnection structure 126 may be electrically connected to the conductive region 122 and/or the individual devices ID.

The redistribution layer 128 may be a conductive pattern layer electrically connecting the first connection pad 120P1 and the second connection pad 120P2 on the interconnection structure 126 to each other. A dielectric layer 127 may be disposed between the redistribution layer 128 and the circuit layer 120C. The dielectric layer 127 may cover the uppermost interconnection structure 126. The dielectric layer 127 may include an inorganic insulating film or an organic insulating film. In an embodiment, the first connection pad 120P1 may be electrically connected to the interconnection structure 126 through a connection via CV penetrating through the dielectric layer 127. The redistribution layer 128 may be covered by a passivation layer PSV. The passivation layer PSV may have an opening exposing at least a portion of each of the connection pads 120P1, 120P2, and 120P3. For example, in an embodiment the passivation layer PSV may expose a central portion of each of the connection pads 120P1, 120P2, 120P3 and cover lateral ends of the connection pads 120P1, 120P2, 120P3. The passivation layer PSV may include a single-layer or multilayer insulating film. For example, in an embodiment the passivation layer PSV may include an oxide film and/or a nitride film. In some embodiments, the passivation layer PSV may include a photosensitive polyimide (PSPI).

The lower semiconductor chips (e.g., 120a, 120b, 120c, and 120d) and the upper semiconductor chips (e.g., 120f, 120g, and 120h) may include the semiconductor layer 120B and the circuit layer 120C described above. In an embodiment, the first connection pad 120P1 and the third connection pad 120P3 of each of the lower semiconductor chips (e.g., 120a, 120b, 120c, and 120d) and the upper semiconductor chips (e.g., 120f, 120g, and 120h) may be provided by the uppermost pattern of the interconnection structure 126. For example, the passivation layer PSV may be formed directly on the uppermost pattern of the interconnection structure 126. In an embodiment, the uppermost pattern of the interconnection structure 126 may include, for example, aluminum (Al) or an aluminum (Al) alloy. However, embodiments of the present disclosure are not necessarily limited thereto.

In an embodiment, the plurality of semiconductor chips 120 may include a first group of semiconductor chips SCG1 and a second group of semiconductor chips SCG2 stacked on the first group of semiconductor chips SCG1 (e.g., in the Z-direction). In an embodiment, one semiconductor chip (120d or 120e) among the uppermost semiconductor chip (e.g., 120d) of the first group of semiconductor chips SCG1 and the lowermost semiconductor chip (e.g., 120e) of the second group of semiconductor chips SCG2 may further include second connection pads 120P2 electrically connected to the first connection pads 120P1, respectively. However, embodiments of the present inventive concept are not necessarily limited thereto and any one semiconductor chip generally in the middle of the at least one chip stack CS may be an intermediate semiconductor chip including the second connection pads 120P2. The first group of semiconductor chips SCG1 and the second group of semiconductor chips SCG2 may be electrically connected to each other through first bonding wires 130a connecting the first connection pads 120P1 to each other. The first group of semiconductor chips SCG1 and the second group of semiconductor chips SCG2 may be electrically connected to the first bonding pads 111 of the substrate 110 through second bonding wires 130b connected to the second connection pads 120P2. In an embodiment, the first group of semiconductor chips SCG1 and the second group of semiconductor chips SCG2 may include the same number of semiconductor chips (e.g., 4) as each other. However, embodiments of the present disclosure are not necessarily limited thereto.

The bonding wires 130 may electrically connect a plurality of semiconductor chips 120 to the substrate 110. In an embodiment, the bonding wires 130 may include, but are not necessarily limited to, gold (Au), silver (Ag), lead (Pb), aluminum (Al), copper (Cu), or alloys thereof. The bonding wires 130 may include a first bonding wire 130a connecting the first connection pads 120P1 of each of the plurality of semiconductor chips 120 to each other, a second bonding wire 130b connecting the second connection pad 120P2 of the intermediate semiconductor chip (e.g., 120e) to the first bonding pad 111, and a third bonding wire 130c connecting the third connection pad 120P3 of each of the plurality of semiconductor chips 120 to the second bonding pad 112. The second bonding wire 130b may form a channel for the plurality of semiconductor chips 120 constituting a single chip stack CS, for example, the first group of semiconductor chips SCG1 and the second group of semiconductor chips SCG2. According to an embodiment, the second bonding wire 130b may form a branch point of a signal path between the first group of semiconductor chips SCG1 and the second group of semiconductor chips SCG2, thereby minimizing signal reflection and increasing signal integrity (SI) characteristics.

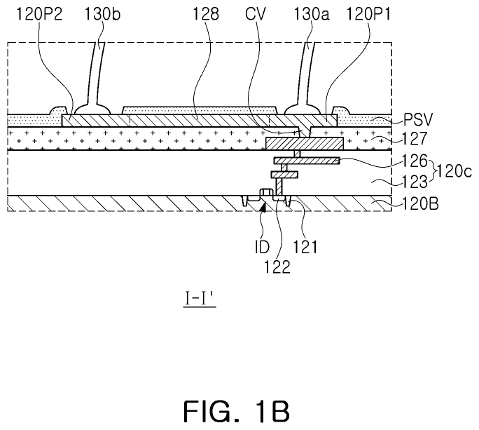

FIG. 2A is a perspective view of a semiconductor package 100B according to an embodiment, and FIG. 2B is a cross-sectional view taken along line II-II′ of FIG. 2A.

Referring to FIGS. 2A and 2B, the semiconductor package 100B of the embodiment may have the same or similar features as those described above with reference to FIGS. 1A and 1B, except that at least one lower semiconductor chip (e.g., 120a, 120b, 120c, and 120d) includes a fourth connection pad 120P4. Therefore, a repeated description of similar or identical elements shown in embodiments of FIGS. 1A-1B may be omitted for economy of description.

In an embodiment, at least one semiconductor chip (e.g., 120c) among the first group of semiconductor chips SCG1 may further include fourth connection pads 120P4. The fourth connection pads 120P4 may be electrically insulated from the first connection pads 120P1. At least one semiconductor chip (e.g., 120c) including the fourth connection pad 120P4 may be located below an intermediate semiconductor chip (e.g., 120e).

In an embodiment, the at least one semiconductor chip (e.g., 120c) may be provided in a number greater than one as illustrated in FIG. 2A. For example, two or more semiconductor chips among the first semiconductor chip 120a, the second semiconductor chip 120b, the third semiconductor chip 120c, and the fourth semiconductor chip 120d sequentially stacked below the intermediate semiconductor chip (e.g., 120e) may include the fourth connection pad 120P4.

The second bonding wire 130b may be further connected to the fourth connection pad 120P4 between the second connection pad 120P2 and the first bonding pad 111. The fourth connection pads 120P4 may increase the structural stability of the second bonding wire 130b.

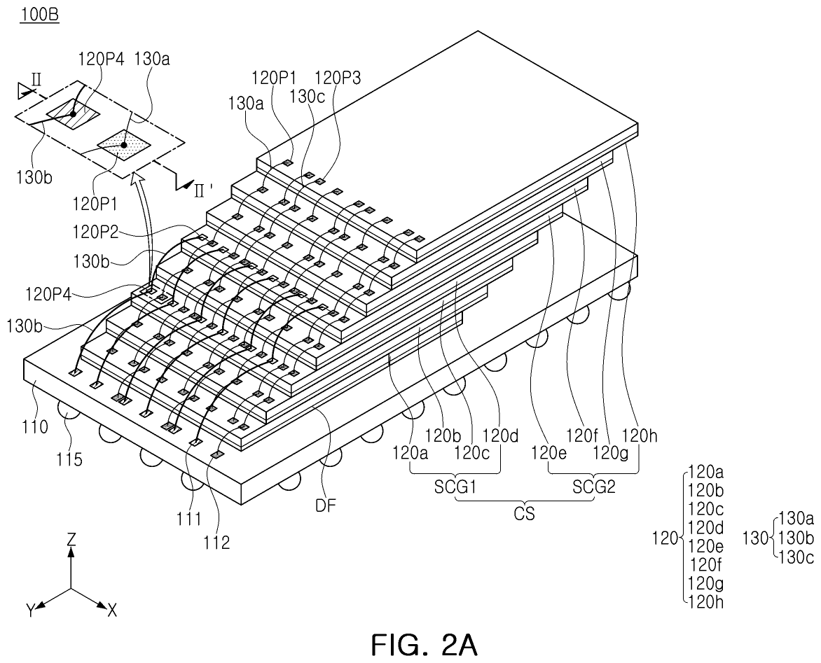

FIG. 3 is a perspective view of a semiconductor package 100C according to an embodiment.

Referring to FIG. 3, the semiconductor package 100C of an embodiment may have the same or similar features as those described above with reference to FIGS. 1A to 2B, except that it includes a plurality of chip stacks CS1 and CS2. Therefore, a repeated description of similar or identical elements shown in embodiments of FIGS. 1A-2B may be omitted for economy of description.

In an embodiment, the semiconductor package 100C may include a plurality of semiconductor chips 120 constituting a first chip stack CS1 and a second chip stack CS2. For example, in an embodiment the plurality of semiconductor chips 120 may include a first semiconductor chip 120a, a second semiconductor chip 120b, a third semiconductor chip 120c, and a fourth semiconductor chip 120d constituting the first chip stack CS1 and a fifth semiconductor chip 120e, a sixth semiconductor chip 120f, a seventh semiconductor chip 120g, and an eighth semiconductor chip 120h constituting the second chip stack CS2.

The first chip stack CS1 and the second chip stack CS2 may include the first group of semiconductor chips SCG1 and the second group of semiconductor chips SCG2, respectively, as described above. In an embodiment, the first chip stack CS1 may include the first group of semiconductor chips SCG1 including the first semiconductor chip 120a and the second semiconductor chip 120b and the second group of semiconductor chips SCG2 including the third semiconductor chip 120c and the fourth semiconductor chip 120d. The second chip stack CS2 may include the first group of semiconductor chips SCG1 including the fifth semiconductor chip 120e and the sixth semiconductor chip 120f and the second group of semiconductor chips SCG2 including the seventh semiconductor chip 120g and the eighth semiconductor chip 120h.

In an embodiment, the first chip stack CS1 may include an intermediate semiconductor chip, for example, the second semiconductor chip 120b, including the second connection pad 120P2. The second chip stack CS2 may include an intermediate semiconductor chip, for example, the sixth semiconductor chip 120f, including the second connection pad 120P2. The first chip stack CS1 and the second chip stack CS2 may each be electrically connected to the first bonding pad 111 of the substrate 110 via the separate second bonding wire 130b. In an embodiment, the first bonding pad 111 may include a first pad 111a connected to the first chip stack CS1 and a second pad 111b connected to the second chip stack CS2. The second connection pad 120P2 of the second semiconductor chip 120b may be connected to (e.g., electrically connected thereto) the first pad 111a via the second bonding wire 130b. The second connection pad 120P2 of the sixth semiconductor chip 120f may be connected to (e.g., electrically connected thereto) the second pad 111b via the second bonding wire 130b. The first chip stack CS1 and the second chip stack CS2 may be electrically insulated from each other in terms of data signals. The first connection pads 120P1 of the first chip stack CS1 may be electrically insulated from the first connection pads 120P1 of the second chip stack CS2.

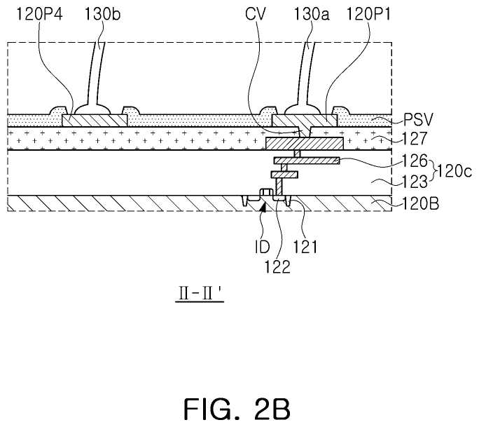

FIG. 4 is a perspective view of a semiconductor package 100D according to an embodiment.

Referring to FIG. 4, the semiconductor package 100D of an embodiment may have the same or similar features as those described above with reference to FIGS. 1A to 3, except that it further includes an additional semiconductor chip 140. Therefore, a repeated description of similar or identical elements shown in embodiments of FIGS. 1A-3 may be omitted for economy of description. The additional semiconductor chip 140 is mounted on the substrate 110 (e.g., mounted directly on an upper surface thereof) and may be electrically connected to at least some of the second bonding wires 130b. The additional semiconductor chip 140 may control access to data stored in a plurality of semiconductor chips 120. In an embodiment, the additional semiconductor chip 140 may control write/read operations of the plurality of semiconductor chips 120 according to a control command of an external host. The additional semiconductor chip 140 may perform wear leveling, garbage collection, bad block management, and error correcting code (ECC). For example, the additional semiconductor chip 140 may include a controller chip or a buffer chip. At least some of the second bonding wires 130b may include a first portion 130b1 connecting (e.g., electrically connecting) the second connection pads 120P2 to connection terminals 140P of the additional semiconductor chip 140 and a second portion 130b2 connecting (e.g., electrically connecting) the connection terminals 140P of the additional semiconductor chip 140 to the first bonding pads 111 of the substrate 110.

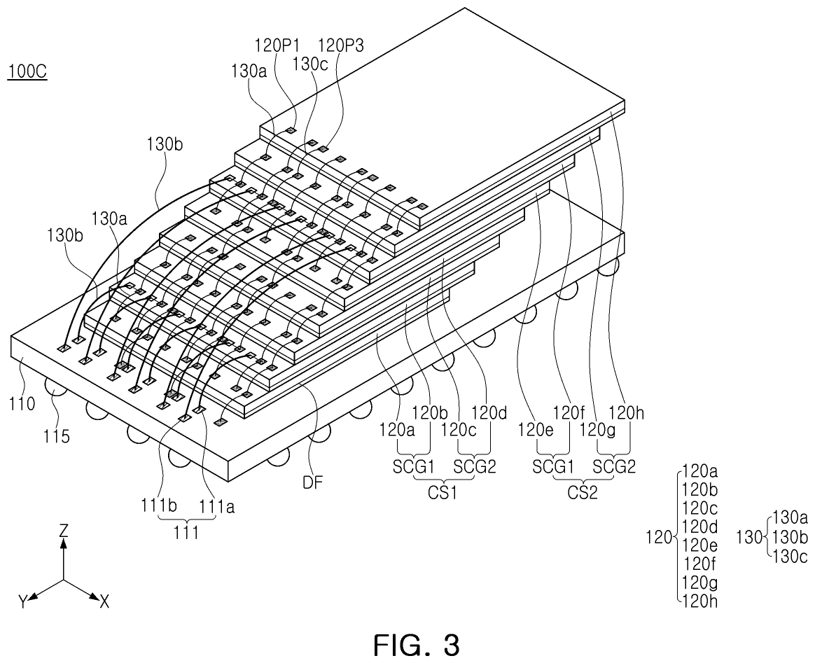

Hereinafter, an effect of increasing signal characteristics of a semiconductor package according to an embodiment will be described with reference to FIGS. 5 to 8.

FIG. 5 is a view illustrating a storage system 1 according to the embodiment.

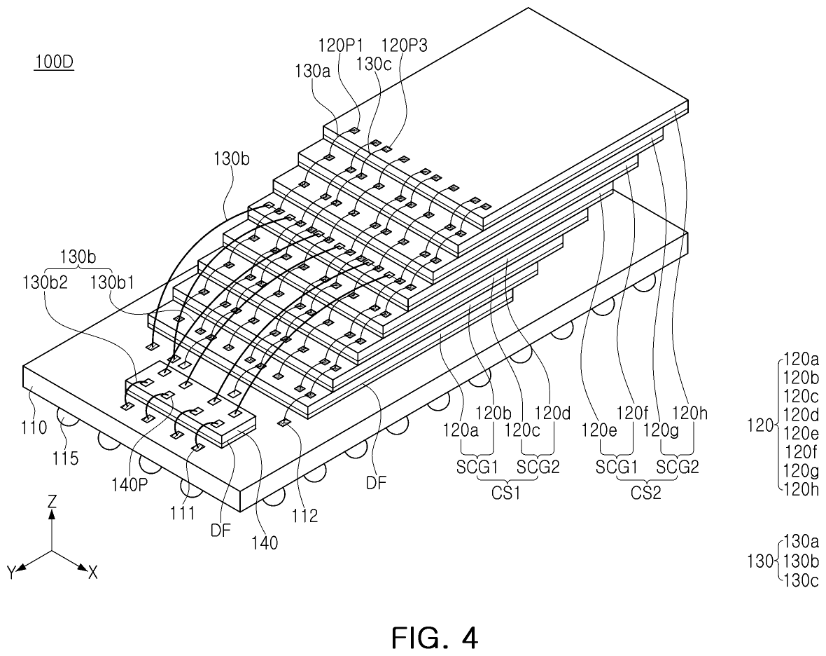

FIG. 6 is a view illustrating a storage system 1′ according to a comparative example.

Referring to FIG. 5, the storage system 1 of an embodiment may include a storage device 10, a control device 20, and a host 30.

The storage device 10 may be understood as a semiconductor package having the same or similar characteristics as those of the semiconductor packages 100A, 100B, 100C, and 100D of FIGS. 1A to 4. In an embodiment, the storage device 10 may include a chip stack CS including a plurality of memory chips SC1, SC2, SC3, SC4, SC5, SC6, SC7, and SC8. However, embodiments of the present disclosure are not necessarily limited thereto and the storage device 10 may include more or fewer memory chips than those illustrated in FIG. 5. The plurality of memory chips SC1, SC2, SC3, SC4, SC5, SC6, SC7, and SC8 may include nonvolatile memory chips and/or volatile memory chips and may function as a storage medium of the storage device 10.

The control device 20 may be connected to (e.g., electrically connected thereto) the host 30 through a first signal transmission line SGL1 and to the chip stack CS through a second signal transmission line SGL2. In an embodiment, the control device 20 may be connected to each of a plurality of memory chips SC1, SC2, SC3, SC4, SC5, SC6, SC7, and SC8 constituting the chip stack CS through a single channel provided by the first signal transmission line SGL1. According to an embodiment, the control device 20 may be located inside the storage device 10.

In an embodiment, the control device 20 may transmit and receive control signals, such as commands, addresses, and/or data through the first signal transmission line SGL1. The control device 20 may write data to or read data from the plurality of memory chips SC1, SC2, SC3, SC4, SC5, SC6, SC7, and SC8 according to a command of the host 30.

In an embodiment, a first branch point BP1 of the second signal transmission line SGL2 may be formed in the middle of the chip stack CS. Accordingly, a difference between a signal transmission distance from one end (e.g., ‘SC1’) of the chip stack CS to the first branch point BP1 and a signal transmission distance from the other end (e.g., ‘SC8’) of the chip stack CS to the first branch point BP1 may be minimized and the signal integrity (SI) characteristics may be increased. For example, the first branch point BP1 may be provided by a ‘branch pad (e.g., the second connection pad 120P2 of FIG. 1A) formed on one of the memory chips (SC4 or SC5) among the uppermost memory chip (e.g., SC4) of the chips SCG1 of the first group and the lowermost memory chip (e.g., SC5) of the chips SCG2 of the second group. In addition, the second signal transmission line SGL2 may be provided by a bonding wire (e.g., the second bonding wire 130b of FIG. 1A) connected to (e.g., electrically connected thereto) the ‘branch pad (‘120P2’ of FIG. 1A).

In an embodiment, the control device 20 may be supplied with power from the host 30 through a first power supply line PWL1. The storage device 10 may be supplied with power from the host 30 through a second power supply line PWL2. A second branch point BP2 of the second power supply line PWL2 may be formed at one end (e.g., ‘SC1’) of the chip stack CS.

Referring to FIG. 6, a storage system 1′ of a comparative example may have the same or similar features as those described above with reference to FIG. 5, except for a location of the first branch point BP1. In the comparative example, the first branch point BP1 of the second signal transmission line SGL2 may be formed at one end (e.g., ‘SC1’) of the chip stack CS.

Therefore, the difference between the signal transmission distance from one end (e.g., ‘SC1’) of the chip stack CS to the first branch point BP1 and the signal transmission distance from the other end (e.g., ‘SC8’) of the chip stack CS to the first branch point BP1 may increase and the signal integrity (SI) characteristics may deteriorate (e.g., be reduced). For example, in the comparative embodiment the first branch point BP1 may be provided by the ‘signal pad’ (e.g., the first connection pad 120P1 of FIG. 1A) of the lowermost memory chip (e.g., SC1) among the plurality of memory chips SC1, SC2, SC3, SC4, SC5, SC6, SC7, and SC8.

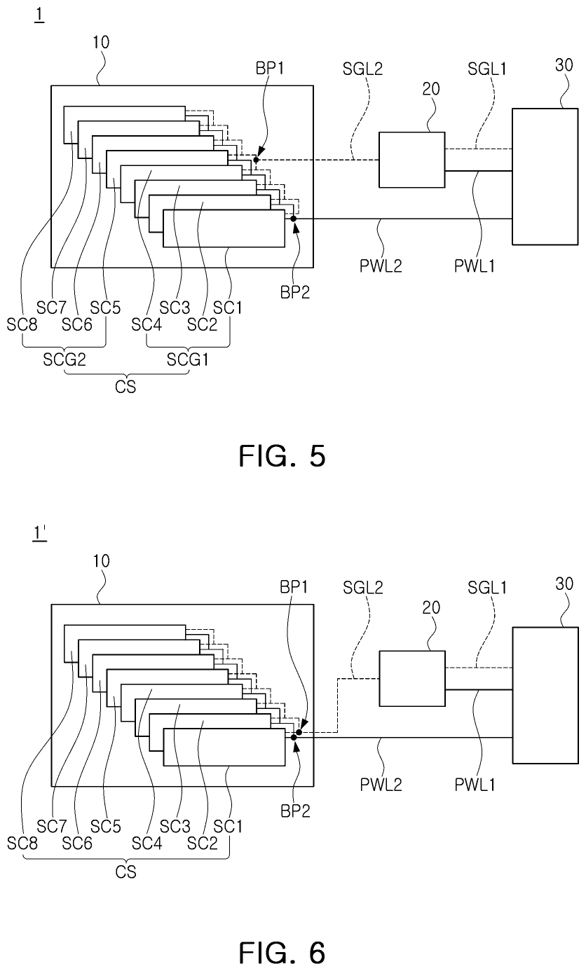

FIG. 7 is an eye diagram ED of a storage device according to an embodiment. FIG. 7 illustrates an eye diagram for the storage device 10 of FIG. 5.

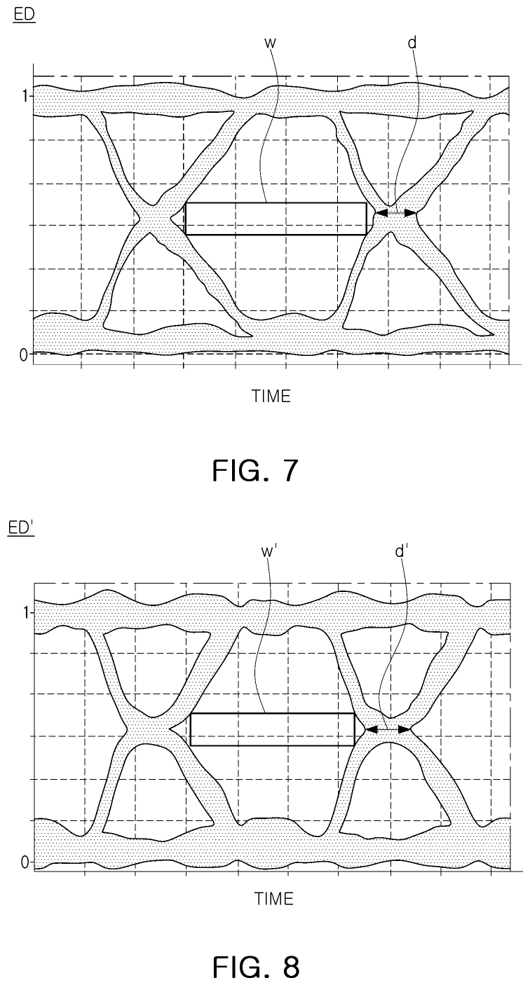

FIG. 8 is an eye diagram ED′ of a storage device according to a comparative example. FIG. 8 illustrates an eye diagram for the storage device 10 of FIG. 6.

Referring to FIGS. 7 and 8, the eye diagram ED of the embodiment has a window width (w) increased compared to a window width w′ of the eye diagram ED′ of the comparative example. In addition, the eye diagram ED of the embodiment has a width d of timing jitter reduced compared to a width d′ of timing jitter of the eye diagram ED′ of the comparative example. In this manner, according to an embodiment of the present inventive concept, the first branch point BP1 of the second signal transmission line SGL2 is formed in the middle of the chip stack CS, thereby minimizing signal reflection and increasing signal integrity (SI) characteristics.

According to embodiments of the present inventive concept, by forming the branch point of the signal transmission line in the middle of the chip stack, the semiconductor package having increased signal characteristics may be provided.

While non-limiting embodiments of the present inventive concept have been illustrated and described above, it will be apparent to those skilled in the art that modifications and variations could be made without departing from the scope of the present inventive concept.

What is claimed is:

1. A semiconductor package comprising:
a substrate including first bonding pads;
at least one chip stack disposed on the substrate, the at least one chip stack including a plurality of semiconductor chips stacked on the substrate, the plurality of semiconductor chips including first connection pads electrically connected to the first bonding pads;
bonding wires electrically connecting the substrate to the at least one chip stack; and
connection bumps arranged below the substrate,
wherein the plurality of semiconductor chips includes a first group of semiconductor chips and a second group of semiconductor chips stacked on the first group of semiconductor chips,
any one of an uppermost semiconductor chip in the first group of semiconductor chips and a lowermost semiconductor chip in the second group of semiconductor chips further includes second connection pads electrically connected to the first connection pads, respectively, and
the bonding wires include first bonding wires electrically connecting the first connection pads of each of the plurality of semiconductor chips to each other, and second bonding wires electrically connecting the second connection pads and the first bonding pads to each other.

2. The semiconductor package of claim 1, wherein the first group of semiconductor chips and the second group of semiconductor chips are electrically connected to each other through the first bonding wires.

3. The semiconductor package of claim 1, wherein the first group of semiconductor chips and the second group of semiconductor chips are electrically connected to the first bonding pads through the second bonding wires.

4. The semiconductor package of claim 1, wherein the first group of semiconductor chips and the second group of semiconductor chips include a same number of semiconductor chips as each other.

5. The semiconductor package of claim 1, wherein the any one semiconductor chip further includes individual devices, an interconnection structure electrically connecting the individual devices to the first connection pads, and a redistribution layer electrically connecting the first connection pads to the second connection pads.

6. The semiconductor package of claim 1, wherein:
the substrate further includes second bonding pads,
the plurality of semiconductor chips further includes third connection pads electrically connected to the second bonding pads, and
the bonding wires further include third bonding wires electrically connecting the third connection pads of each of the plurality of semiconductor chips to the second bonding pads.

7. The semiconductor package of claim 6, wherein the first connection pads include a signal pad, and the third connection pads include a power pad and a ground pad.

8. The semiconductor package of claim 1, wherein the second bonding wires provide a single channel connected to the first group of semiconductor chips and the second group of semiconductor chips.

9. The semiconductor package of claim 1, wherein:
at least one semiconductor chip among the first group of semiconductor chips further includes fourth connection pads electrically insulated from the first connection pads, respectively; and
the second bonding wires are connected to the fourth connection pads.

10. The semiconductor package of claim 9, wherein the at least one semiconductor chip including the fourth connection pads is located below the any one semiconductor chip including the second connection pads.

11. The semiconductor package of claim 1, wherein:
the at least one chip stack includes a first chip stack and a second chip stack, each of the first and second chip stacks includes the first group of semiconductor chips and the second group of semiconductor chips; and
the first connection pads of the first chip stack are electrically insulated from the first connection pads of the second chip stack.

12. The semiconductor package of claim 1, further comprising an additional semiconductor chip disposed on the substrate,
wherein at least some of the second bonding wires include a first portion electrically connecting the second connection pads to the additional semiconductor chip and a second portion electrically connecting the additional semiconductor chip to the first bonding pads.

13. The semiconductor package of claim 12, wherein the additional semiconductor chip includes a buffer chip or a controller chip.

14. A semiconductor package comprising:
a substrate including first bonding pads;
a plurality of semiconductor chips stacked on the substrate, each of the plurality of semiconductor chips includes at least one of a first connection pad or a second connection pad; and
bonding wires electrically connecting the substrate to the plurality of semiconductor chips,
wherein the plurality of semiconductor chips include:
an intermediate semiconductor chip including the first connection pad and the second connection pad electrically connected to the first connection pad;
lower semiconductor chips stacked below the intermediate semiconductor chip, the lower semiconductor chips including the first connection pad; and
upper semiconductor chips stacked on the intermediate semiconductor chip, the upper semiconductor chips including the first connection pad, and
wherein the bonding wires include:
a first bonding wire electrically connecting the first connection pads of each of the intermediate semiconductor chip, the lower semiconductor chips, and the upper semiconductor chips to each other; and
a second bonding wire electrically connecting the second connection pad of the intermediate semiconductor chip to the first bonding pads of the substrate.

15. The semiconductor package of claim 14, wherein a number of the lower semiconductor chips and a number of the upper semiconductor chips are different from each other.

16. The semiconductor package of claim 14, wherein:
the substrate further includes a second bonding pad electrically insulated from the first bonding pads,
the intermediate semiconductor chip, the lower semiconductor chips, and the upper semiconductor chips each further include a third connection pad electrically insulated from the first connection pad; and
the bonding wires further include a third bonding wire electrically connecting the third connection pad of each of the intermediate semiconductor chip, the lower semiconductor chips, and the upper semiconductor chips to the second bonding pad of the substrate.

17. The semiconductor package of claim 14, wherein the plurality of semiconductor chips are offset in a horizontal direction, wherein the first connection pad and the second connection pad are exposed in a vertical direction.

18. A semiconductor package comprising:
a substrate including first and second bonding pads;
a plurality of semiconductor chips stacked on the substrate, each of the plurality of semiconductor chips including a signal pad and a power pad; and
bonding wires electrically connecting the substrate to the plurality of semiconductor chips,
wherein any one semiconductor chip, among the plurality of semiconductor chips, further includes a branch pad electrically connected to the signal pad, and
wherein the bonding wires include:
a first bonding wire electrically connecting the signal pad of each of the plurality of semiconductor chips to each other,
a second bonding wire electrically connecting the branch pad of any one semiconductor chip to the first bonding pad, and
a third bonding wire electrically connecting the power pad of each of the plurality of semiconductor chips to the second bonding pad.

19. The semiconductor package of claim 18, wherein the plurality of semiconductor chips further includes one or more lower semiconductor chips stacked below the any one semiconductor chip and one or more upper semiconductor chips stacked above the any one semiconductor chip.

20. The semiconductor package of claim 18, wherein the plurality of semiconductor chips includes a non-volatile memory chip or a volatile memory chip.
